(19) United States
(12) Patent Application Publication
(10) Pub. No.: US 2017/0092899 A1
(43) Pub. Date: Mar. 30, 2017

(54) EVAPORATION SOURCE FOR ORGANIC MATERIAL

(71) Applicants: Stefan BANGERT, Steinau (DE); Jose Manuel DIEGUEZ-CAMPO, Hanau (DE); Uwe SCHÜSSLER, Aschaffenburg (DE); Andreas LOPP, Freigericht-Somborn (DE); Applied Materials, Inc., Santa Clara, CA (US)

(72) Inventors: Stefan BANGERT, Steinau (DE); Jose Manuel DIEGUEZ-CAMPO, Hanau (DE); Uwe SCHÜSSLER, Aschaffenburg (DE); Andreas LOPP, Freigericht-Somborn (DE)

(21) Appl. No.: 15/126,565

(22) PCT Filed: Mar. 21, 2014
(86) PCT No.: PCT/EP2014/055741

§ 371 Date: Sep. 15, 2016

(51) Int. Cl. H01L 51/56; C23C 14/26; H01L 51/00; C23C 14/24

(52) U.S. Cl. CPC H01L 51/56; C23C 14/243; C23C 14/26; H01L 51/001; H01L 51/0011; H01L 51/0012

(57) ABSTRACT

An evaporation source for organic material is described. The evaporation source includes an evaporation crucible, wherein the evaporation crucible is configured to evaporate the organic material, a distribution pipe with one or more outlets provided along the length of the distribution pipe, wherein the distribution pipe is in fluid communication with the evaporation crucible, and wherein the distribution pipe has a cross-section perpendicular to the length of the distribution pipe, which is non-circular, and which includes: an outlet side at which the one or more outlets are provided, wherein the width of the outlet side of the cross-section is 30% or less of the maximum dimension of the cross-section.

### TECHNICAL FIELD OF THE INVENTION

Embodiments of the present invention relate to deposition of organic material, a system for depositing materials, e.g. organic materials, a source for organic material and deposition apparatuses for organic material. Embodiments of the present invention particularly relate to evaporation sources for organic material, e.g. for evaporation apparatuses and/or manufacturing systems for manufacturing devices, particularly devices including organic materials therein and to evaporation source arrays for organic material, e.g. for evaporation apparatuses and/or manufacturing systems for manufacturing devices, particularly devices including organic materials therein and to evaporation source arrays.

### BACKGROUND OF THE INVENTION

Organic evaporators are a tool for the production of organic light-emitting diodes (OLED). OLEDs are a special type of light-emitting diodes in which the emissive layer comprises a thin-film of certain organic compounds. Organic light emitting diodes (OLEDs) are used in the manufacture of television screens, computer monitors, mobile phones, other hand-held devices, etc., for displaying information. OLEDs can also be used for general space illumination. The range of colors, brightness, and viewing angle possible with OLED displays are greater than that of traditional LCD displays because OLED pixels directly emit light and do not require a back light. Therefore, the energy consumption of OLED displays is considerably less than that of traditional LCD displays. Further, the fact that OLEDs can be manufactured onto flexible substrates results in further applications. A typical OLED display, for example, may include layers of organic material situated between two electrodes that are all deposited on a substrate in a manner to form a matrix display panel having individually energizable pixels. The OLED is generally placed between two glass panels, and the edges of the glass panels are sealed to encapsulate the OLED therein.

There are many challenges encountered in the manufacture of such display devices. In one example, there are numerous labor intensive steps necessary to encapsulate the OLED between the two glass panels to prevent possible contamination of the device. In another example, different sizes of display screens and thus glass panels may require substantial reconfiguration of the process and process hardware used to form the display devices. Generally, there is a desire to manufacture OLED devices on large area substrates.

One step in the manufacturing of large scale OLED displays, which brings about various challenges, is the masking of the substrate, e.g. for deposition of patterned layers. Further, known systems typically have a small overall material utilization, e.g. of <50%.

OLED displays or OLED lighting applications include a stack of several organic materials, which are for example evaporated in vacuum. The organic materials are deposited in a subsequent manner through shadow masks. For the fabrication of OLED stacks with high efficiency the co-deposition or co-evaporation of two or more materials, e.g. host and dopant, leading to mixed/doped layers is desired. Further, it has to be considered that there are requirements for the evaporation of the very sensitive organic materials.

For the production of e.g. OLED Displays, the pixelation of the displays is achieved by depositing the organic material through a shadow mask. To avoid a misalignment of the pixels caused by thermal expansion of the mask induced through the heat load of the evaporation source, shielding and/or cooling of the organic source is desired.

Therefore, there is a continuous need for new and improved systems, apparatuses and methods for forming devices such as OLED display devices.

### SUMMARY OF THE INVENTION

In light of the above, an evaporation source for organic material according to independent claim 1, and an evaporation source array are provided. Further advantages, features, aspects and details are evident from the dependent claims, the description and the drawings.

According to one embodiment, an evaporation source for organic material is provided. The evaporation source includes an evaporation crucible, wherein the evaporation crucible is configured to evaporate the organic material, a distribution pipe with one or more outlets provided along the length of the distribution pipe, wherein the distribution pipe is in fluid communication with the evaporation crucible, and wherein the distribution pipe has a cross-section perpendicular to the length of the distribution pipe, which is non-circular, and which includes: an outlet side at which the one or more outlets are provided, wherein the width of the outlet side of the cross-section is 30% or less of the maximum dimension of the cross-section.

According to another embodiment, an evaporation source array for organic materials is provided. The evaporation source array includes a first evaporation source and at least a second evaporation source, wherein the one or more outlets of the first evaporation source and the one or more outlets of the second evaporation sources have a distance of 25 mm or less. For example each of the evaporation sources include an evaporation crucible, wherein the evaporation crucible is configured to evaporate the organic material, a distribution pipe with one or more outlets provided along the length of the distribution pipe, wherein the distribution pipe is in fluid communication with the evaporation crucible, and wherein the distribution pipe has a cross-section perpendicular to the length of the distribution pipe, which is non-circular, and which includes: an outlet side at which the one or more outlets are provided, wherein the width of the outlet side of the cross-section is 30% or less of the maximum dimension of the cross-section.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic top view of a deposition apparatus for depositing organic material in a vacuum chamber according to embodiments described herein;

FIGS. 2A and 2B show schematic views of portions of an evaporation source according to embodiments described herein;

FIG. 2C shows a schematic view of another evaporation source according to embodiments described herein;

FIGS. 3A to 3C show schematic cross-sectional views of portions of an evaporation source or an evaporation pipe, respectively, according to embodiments described herein;

FIG. 4 shows a schematic cross-sectional view of a portion of an evaporation source or an evaporation pipe, respectively, according to embodiments described herein;

FIG. 5A shows a schematic view of a portion of an evaporation pipe according to embodiments described herein;

FIGS. 5B and 5C show schematic views of portions of an array of openings in shields according to embodiments described herein;

FIG. 6 shows a schematic view of a portion of an evaporation source according to embodiments described herein;

FIGS. 7A and 7B show schematic cross-sectional views of portions of an evaporation source or an evaporation pipe, respectively, according to embodiments described herein;

FIG. 8A shows a schematic view of another evaporation source according to embodiments described herein;

FIG. 8B shows a schematic view of yet another evaporation source according to embodiments described herein;

FIGS. 9A and 9B show schematic views of a deposition apparatus for depositing organic material in a vacuum chamber according to embodiments described herein and evaporation sources for evaporation of organic material according to embodiments described herein in different deposition positions in a vacuum chamber; and

FIG. 10 shows a manufacturing system having a cluster system portion, a vacuum swing module, a transfer chamber, a further transfer chamber, a further vacuum swing module and a further cluster system portion according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

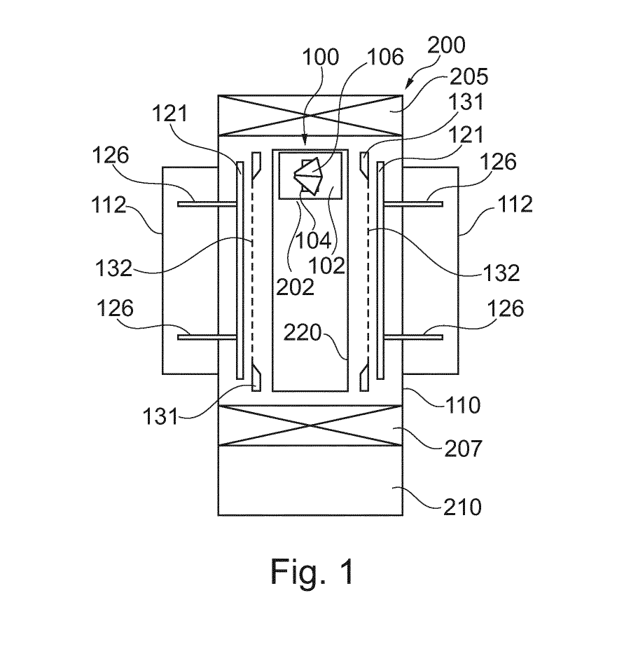

FIG. 1 shows an evaporation source 100 in a position in a vacuum chamber 110. According to some embodiments, which can be combined with other embodiments described herein, the evaporation source is configured for a translational movement and a rotation around an axis. The evaporation source 100 has one or more evaporation crucibles 104 and one or more distribution pipes 106. Two evaporation crucibles and two distribution pipes are shown in FIG. 1. The distribution pipes 106 are supported by the support 102. Further, according to some embodiments, the evaporation crucibles 104 can also be supported by the support 102. Two substrates 121 are provided in the vacuum chamber 110. Typically, a mask 132 for masking of the layer deposition on the substrate can be provided between the substrate and the evaporation source 100. Organic material is evaporated from the distribution pipes 106.

According to embodiments described herein, the substrates are coated with organic material in an essentially vertical position. That is the view shown in FIG. 1 is a top view of an apparatus including the evaporation source 100. Typically, the distribution pipe is a vapor distribution showerhead, particularly a linear vapor distribution showerhead. Thereby, the distribution pipe provides a line source extending essentially vertically. According to embodiments described herein, which can be combined with other embodiments described herein, essentially vertically is understood particularly when referring to the substrate orientation, to allow for a deviation from the vertical direction of 20° or below, e.g. of 10° or below. This deviation can be provided for example because a substrate support with some deviation from the vertical orientation might result in a more stable substrate position. Yet, the substrate orientation during deposition of the organic material is considered essentially vertical, which is considered different from the horizontal substrate orientation. The surface of the substrates is thereby coated by a line source extending in one direction corresponding to one substrate dimension and a translational movement along the other direction corresponding to the other substrate dimension.

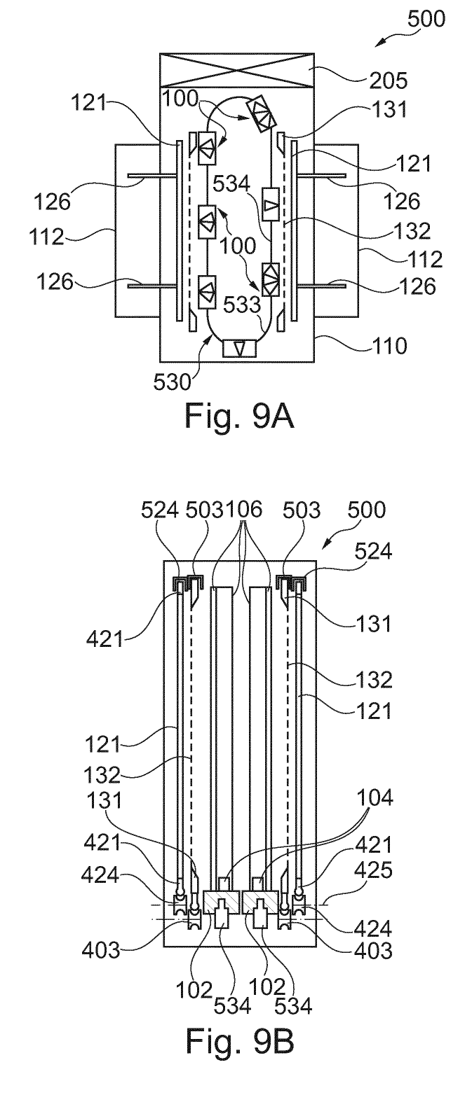

FIG. 1 illustrates an embodiment of a deposition apparatus 200 for depositing organic material in a vacuum chamber 110. The evaporation source 100 is provided in the vacuum chamber 110 on a track, e.g. a looped track (as shown in FIG. 9A) or linear guide 220. The track or the linear guide 220 is configured for the translational movement of the evaporation source 100. Thereby, according to different embodiments, which can be combined with other embodiments described herein, a drive for the translational movement can be provided in the evaporation source 100, at the track or linear guide 220, within the vacuum chamber 110 or a combination thereof. FIG. 1 shows a valve 205, for example a gate valve. The valve 205 allows for a vacuum seal to an adjacent vacuum chamber (not shown in FIG. 1). The valve can be opened for transport of a substrate 121 or a mask 132 into the vacuum chamber 110 or out of the vacuum chamber 110.

According to some embodiments, which can be combined with other embodiments described herein, a further vacuum chamber, such as maintenance vacuum chamber 210 is provided adjacent to the vacuum chamber 110. Thereby the vacuum chamber 110 and the maintenance vacuum chamber 210 are connected with a valve 207. The valve 207 is configured for opening and closing a vacuum seal between the vacuum chamber 110 and the maintenance vacuum chamber 210. The evaporation source 100 can be transferred to the maintenance vacuum chamber 210 while the valve 207 is in an open state. Thereafter, the valve can be closed to provide a vacuum seal between the vacuum chamber 110 and the maintenance vacuum chamber 210. If the valve 207 is closed, the maintenance vacuum chamber 210 can be vented and opened for maintenance of the evaporation source 100 without breaking the vacuum in the vacuum chamber 110.

Two substrates 121 are supported on respective transportation tracks within the vacuum chamber 110. Further, two tracks for providing masks 132 thereon are provided. Thereby, coating of the substrates 121 can be masked by respective masks 132. According to typical embodiments, the masks 132, i.e. a first mask 132 corresponding to a first substrate 121 and a second mask 132 corresponding to a second substrate 121, are provided in a mask frame 131 to hold the mask 132 in a predetermined position.

According to some embodiments, which can be combined with other embodiments described herein, a substrate 121 can be supported by a substrate support 126, which is connected to an alignment unit 112. An alignment unit 112 can adjust the position of the substrate 121 with respect to the mask 132. FIG. 1 illustrates an embodiment where the substrate support 126 is connected to an alignment unit 112. Accordingly, the substrate is moved relative to the mask 132 in order to provide for a proper alignment between the substrate and the mask during deposition of the organic material. According to a further embodiment, which can be combined with other embodiments described herein, alternatively or additionally the mask 132 and/or the mask frame 131 holding the mask 132 can be connected to the alignment unit 112. Thereby, either the mask can be positioned relative to the substrate 121 or the mask 132 and the substrate 121 can both be positioned relative to each other. The alignment units 112, which are configured for adjusting the position between a substrate 121 and a mask 132 relative to each other, allow for a proper alignment of the masking during the deposition process, which is beneficial for high quality or LED display manufacturing.

Examples of an alignment of a mask and a substrate relative to each other include alignment units, which allow for a relative alignment in at least two directions defining a plane, which is essentially parallel to the plane of the substrate and the plane of the mask. For example, an alignment can at least be conducted in an x-direction and a y-direction, i.e. two Cartesian directions defining the above-described parallel plane. Typically, the mask and the substrate can be essentially parallel to each other. Specifically, the alignment can further be conducted in a direction essentially perpendicular to the plane of the substrate and the plane of the mask. Thus, an alignment unit is configured at least for an X-Y-alignment, and specifically for an X-Y-Z-alignment of the mask and the substrate relative to each other. One specific example, which can be combined with other embodiments described herein, is to align the substrate in x-direction, y-direction and z-direction to a mask, which can be held stationary in the vacuum chamber 110.

As shown in FIG. 1, the linear guide 220 provides a direction of the translational movement of the evaporation source 100. On both sides of the evaporation source 100 a mask 132 is provided. The masks 132 can thereby extend essentially parallel to the direction of the translational movement. Further, the substrates 121 at the opposing sides of the evaporation source 100 can also extend essentially parallel to the direction of the translational movement. According to typical embodiments, a substrate 121 can be moved into the vacuum chamber 110 and out of the vacuum chamber 110 through valve 205. Thereby, a deposition apparatus 200 can include a respective transportation track for transportation of each of the substrates 121. For example, the transportation track can extend parallel to the substrate position shown in FIG. 1 and into and out of the vacuum chamber 110.

Typically, further tracks are provided for supporting the mask frames 131 and thereby the masks 132. Accordingly, some embodiments, which can be combined with other embodiments described herein, can include four tracks within the vacuum chamber 110. In order to move one of the masks 132 out of the chamber, for example for cleaning of the mask, the mask frame 131 and, thereby, the mask can be moved onto the transportation track of the substrate 121. The respective mask frame can then exit or enter the vacuum chamber 110 on the transportation track for the substrate. Even though it would be possible to provide a separate transportation track into and out of the vacuum chamber 110 for the mask frames 131, the costs of ownership of a deposition apparatus 200 can be reduced if only two tracks, i.e. transportation tracks for a substrate, extend into and out of the vacuum chamber 110 and, in addition, the mask frames 131 can be moved onto a respective one of the transportation tracks for the substrate by an appropriate actuator or robot.

FIG. 1 illustrates an exemplary embodiment of the evaporation source 100. The evaporation source 100 includes a support 102. The support 102 is configured for the translational movement along the linear guide 220. The support 102 supports two evaporation crucibles 104 and two distribution pipes 106 provided over the evaporation crucible 104. Thereby, the vapor generated in the evaporation crucible can move upwardly and out of the one or more outlets of the distribution pipe. According to embodiments described herein, the distribution pipe 106 can also be considered a vapor distribution showerhead, for example a linear vapor distribution showerhead.

According to embodiments described herein, an evaporation source includes one or more evaporation crucibles and one or more distribution pipes, wherein a respective one of the one or more distribution pipes can be in fluid communication with the respective one of the one or more evaporation crucibles. Various applications for OLED device manufacturing include processing steps, wherein two or more organic materials are evaporated simultaneously. Accordingly, as for example shown in FIG. 1, two distribution pipes and corresponding evaporation crucibles can be provided next to each other. Accordingly, the evaporation source 100 may also be referred to as an evaporation source array, e.g. wherein more than one kind of organic material is evaporated at the same time. As described herein, the evaporation source array itself can be referred to as an evaporation source for two or more organic materials.

The one or more outlets of the distribution pipe can be one or more openings or one or more nozzles, which can, e.g., be provided in a showerhead or another vapor distribution system. The evaporation source can include a vapor distribution showerhead, e.g. a linear vapor distribution showerhead having a plurality of nozzles or openings. A showerhead can be understood herein, to include an enclosure having openings such that the pressure in the showerhead is higher than that outside of the showerhead, for example by at least one order of magnitude.

According to embodiments described herein, which can be combined with other embodiments described herein, the rotation of the distribution pipe can be provided by a rotation of an evaporator control housing, on which at least the distribution pipe is mounted. Additionally or alternatively, the rotation of the distribution pipe can be provided by moving the evaporation source along the curved portion off a looped track (see, for example, FIG. 9A). Typically, also the evaporation crucible is mounted on the evaporator control housing. Accordingly, the evaporation sources include a distribution pipe and an evaporation crucible, which may both, i.e. together, rotatably mounted.

According to embodiments described herein, evaporation sources for organic materials or evaporation source arrays, respectively, can be improved with respect to at least two desires, which may be provided independently from one another or in combination. Firstly, evaporation sources evaporating one or more organic materials may suffer from an insufficient mixture of the organic materials when depositing the two or more organic materials on a substrate. Accordingly, it is desirable to improve mixing of organic materials for applications, for which, for example, two different organic materials are deposited to provide one organic layer on a substrate. A corresponding application can, for example, be deposition of a doped layer, wherein a host and one or more dopants are provided. Secondly, as exemplarily described with respect to FIG. 1, many applications require masking of the substrate during deposition of organic material. In light of the fact that the masking step typically requires high precision, a thermal expansion of the mask needs to be reduced. Embodiments described herein, allow for an improved temperature stability of the mask and/or a reduced heat load at the position of the mask, which may be generated by an evaporation source.

According to some embodiments, which can be combined with other embodiments described herein, the evaporation source includes a distribution pipe (e.g. an evaporation tube). The distribution pipe may have a plurality of openings, such as an implemented nozzle array. Further, the evaporation source includes a crucible, which contains the evaporation material. According to some embodiments, which can be combined with other embodiments described herein, the distribution pipe or evaporation tube can be designed in a triangular shape, so that it is possible to bring the openings or the nozzle arrays as close as possible to each other. This allows for achieving an improved mixture of the different organic materials, e.g. for the case of the co-evaporation of two, three or even more different organic materials.

According to yet further embodiments, which can additionally or alternatively be implemented, evaporation sources described herein allow for temperature variation at the position of the mask, which can be, for example, below 5 Kelvin, or even below 1 K. The reduction of the heat transfer from evaporation source to the mask can be provided by an improved cooling. Additionally or alternatively, in light of the triangular shape of the evaporation source, the area, which radiates towards the mask, is reduced. Additionally, a stack of metal plates, for example up to 10 metal plates, can be provided to reduce the heat transfer from the evaporation source to the mask. According to some embodiments, which can be combined with other embodiments described herein, the heat shields or metal plates can be provided with orifices for the outlet or nozzles and may be attached to at least the front side of the source, i.e. the side facing the substrate.

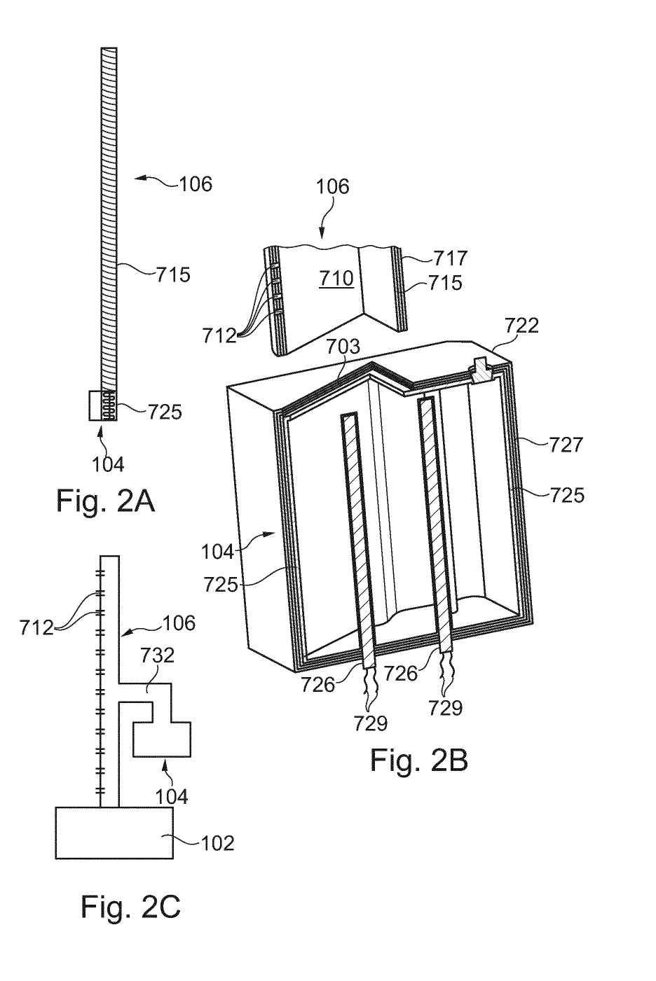

FIGS. 2A to 2C show portions of an evaporation source according to embodiments described herein. An evaporation source can include a distribution pipe 106 and an evaporation crucible 104 as shown in FIG. 2A. Thereby, for example, the distribution pipe can be an elongated cube with heating unit 715. The evaporation crucible can be a reservoir for the organic material to be evaporated with a heating unit 725. According to typical embodiments, which can be combined with other embodiments described herein, distribution pipe 106 provides a line source. For example, a plurality of openings and/or outlets, such as nozzles, are arranged along at least one line. According to an alternative embodiment, one elongated opening extending along the at least one line can be provided. For example, the elongated opening can be a slit. According to some embodiments, which can be combined with other embodiments described herein, the line extends essentially vertically. For example, the length of the distribution pipe 106 corresponds at least to the height of the substrate to be deposited in the deposition apparatus. In many cases, the length of the distribution pipe 106 will be longer than the height of the substrate to be deposited, at least by 10% or even 20%. Thereby, a uniform deposition at the upper end of the substrate and/or the lower end of the substrate can be provided.

According to some embodiments, which can be combined with other embodiments described herein, the length of the distribution pipe can be 1.3 m or above, for example 2.5 m or above. According to one configuration, as shown in FIG. 2A, the evaporation crucible 104 is provided at the lower end of the distribution pipe 106. The organic material is evaporated in the evaporation crucible 104. The vapor of organic material enters the distribution pipe 106 at the bottom of the distribution pipe and is guided essentially sideways through the plurality of openings in the distribution pipe, e.g. towards an essentially vertical substrate.

According to some embodiments, which can be combined with other embodiments described herein, the outlets (e.g. nozzles) are arranged to have a main evaporation direction to be horizontal+−20°. According to some specific embodiments, the evaporation direction can be oriented slightly upward, e.g. to be in a range from horizontal to 15° upward, such as 3° to 7° upward. Correspondingly, the substrate can be slightly inclined to be substantially perpendicular to the evaporation direction. Thereby, undesired particle generation can be reduced. For illustrative purposes, the evaporation crucible 104 and the distribution pipe 106 are shown without heat shields in FIG. 2A. Thereby, the heating unit 715 and the heating unit 725 can be seen in the schematic perspective view shown in FIG. 2A.

FIG. 2B shows an enlarged schematic view of a portion of the evaporation source, wherein the distribution pipe 106 is connected to the evaporation crucible 104. A flange unit 703 is provided, which is configured to provide a connection between the evaporation crucible 104 and the distribution pipe 106. For example the evaporation crucible and the distribution pipe are provided as separate units, which can be separated and connected or assembled at the flange unit, e.g. for operation of the evaporation source.

The distribution pipe 106 has an inner hollow space 710. A heating unit 715 is provided to heat the distribution pipe. Accordingly, the distribution pipe 106 can be heated to a temperature such that the vapor of the organic material, which is provided by the evaporation crucible 104, does not condense at an inner portion of the wall of the distribution pipe 106. Two or more heat shields 717 are provided around the tube of the distribution pipe 106. The heat shields are configured to reflect heat energy provided by the heating unit 715 back towards the hollow space 710. Thereby, the energy required to heat the distribution pipe, i.e. the energy provided to the heating unit 715, can be reduced because the heat shields 717 reduce heat losses. Further, heat transfer to other distribution pipes and/or to the mask or substrate can be reduced. According to some embodiments, which can be combined with other embodiments described herein the heat shields 717 can include two or more heat shield layers, e.g. five or more heat shield layers, such as ten heat shield layers.

Typically, as shown in FIG. 2B, the heat shields 717 include openings at positions of the opening or outlet 712 in the distribution pipe 106. The enlarged view of the evaporation source shown in FIG. 2B shows four openings or outlet 712. The openings or outlets 712 can be provided along one or more lines, which are essentially parallel to the axis of the distribution pipe 106. As described herein, the distribution pipe 106 can be provided as a linear distribution showerhead, for example, having a plurality of openings disposed therein. Thereby, a showerhead as understood herein has an enclosure, hollow space, or pipe, in which the material can be provided or guided, for example from the evaporation crucible. The showerhead can have a plurality of openings (or an elongated slit) such that the pressure within the showerhead is higher than outside of the showerhead. For example, the pressure within the showerhead can be at least one order of magnitude higher than that outside of the showerhead.

During operation, the distribution pipe 106 is connected to the evaporation crucible 104 at the flange unit 703. The evaporation crucible 104 is configured to receive the organic material to be evaporated and to evaporate the organic material. FIG. 2B shows a cross-section through the housing of the evaporation crucible 104. A refill opening is provided, for example, at an upper portion of the evaporation crucible, which can be closed using a plug 722, a lid, a cover or the like for closing the enclosure of evaporation crucible 104.

An outer heating unit 725 is provided within the enclosure of the evaporation crucible 104. The outer heating element can extend at least along a portion of the wall of the evaporation crucible 104. According to some embodiments, which can be combined with other embodiments described herein, one or more central heating elements 726 can additionally or alternatively be provided. FIG. 2B shows two central heating elements 726. The central heating elements 726 can include conductors 729 for providing electrical power to the central heating elements. According to some implementations, the evaporation crucible 104 can further include a shield 727. The shield 727 can be configured to reflect heat energy, which is provided by the outer heating unit 725 and, if present, the central heating elements 726, back into the enclosure of the evaporation crucible 104. Thereby, efficient heating of the organic material within the evaporation crucible 104 can be provided.

According to some embodiments, which have been described herein, heat shields such as shield 717 and shield 727 can be provided for the evaporation source. The heat shields can reduce energy loss from the evaporation source. Thereby, energy consumption can be reduced. However, as a further aspect, particularly for deposition of organic materials, heat radiation originating from the evaporation source can be reduced, particularly heat radiation towards the mask and the substrate during deposition. Particularly for deposition of organic materials on masked substrates, and even more for display manufacturing, the temperature of the substrate and the mask needs to be precisely controlled. Thus, heat radiation originating from the evaporation source can be reduced or avoided. Accordingly, some embodiments described herein include heat shields such as shield 717 and shield 727.

These shields can include several shielding layers to reduce the heat radiation to the outside of the evaporation source. As a further option, the heat shields may include shielding layers, which are actively cooled by a fluid, such as air, nitrogen, water or other appropriate cooling fluids. According to yet further embodiments, which can be combined with other embodiments described herein, the one or more heat shields provided for the evaporation source can include sheet metals surrounding the respective portions of the evaporation sources, such as the distribution pipe 106 and/or the evaporation crucible 104. For example, the sheet metals can have thicknesses of 0.1 mm to 3 mm, can be selected from at least one material selected from the group consisting of ferrous metals (SS) and non-ferrous metals (Cu, Ti, Al), and/or can be spaced with respect to each other, for example by a gap of 0.1 mm or more.

According to some embodiments, as exemplarily shown with respect to FIGS. 2A to 2B, the evaporation crucible 104 is provided at a lower side of the distribution pipe 106. According to yet further embodiments, which can be combined with other embodiments described herein, a vapor conduit 732 can be provided to the distribution pipe 106 at the central portion of the distribution pipe or at another position between the lower end of the distribution pipe and the upper end of the distribution pipe. FIG. 2C illustrates an example of the evaporation source having a distribution pipe 106 and a vapor conduit 732 provided at a central portion of the distribution pipe. Vapor of organic material is generated in the evaporation crucible 104 and is guided through the vapor conduit 732 to the central portion of the distribution pipes 106. The vapor exits the distribution pipe 106 through a plurality of openings or outlets 712. The distribution pipe 106 is supported by a support 102 as described with respect to other embodiments described herein. According to yet further embodiments, which can be combined with other embodiments described herein, two or more vapor conduits 732 can be provided at different positions along the length of the distribution pipe 106. Thereby, the vapor conduits 732 can either be connected to one evaporation crucible 104 or to several evaporation crucibles 104. For example, each vapor conduit 732 can have a corresponding evaporation crucible 104. Alternatively, the evaporation crucible 104 can be in fluid communication with two or more vapor conduits 732, which are connected to the distribution pipe 106.

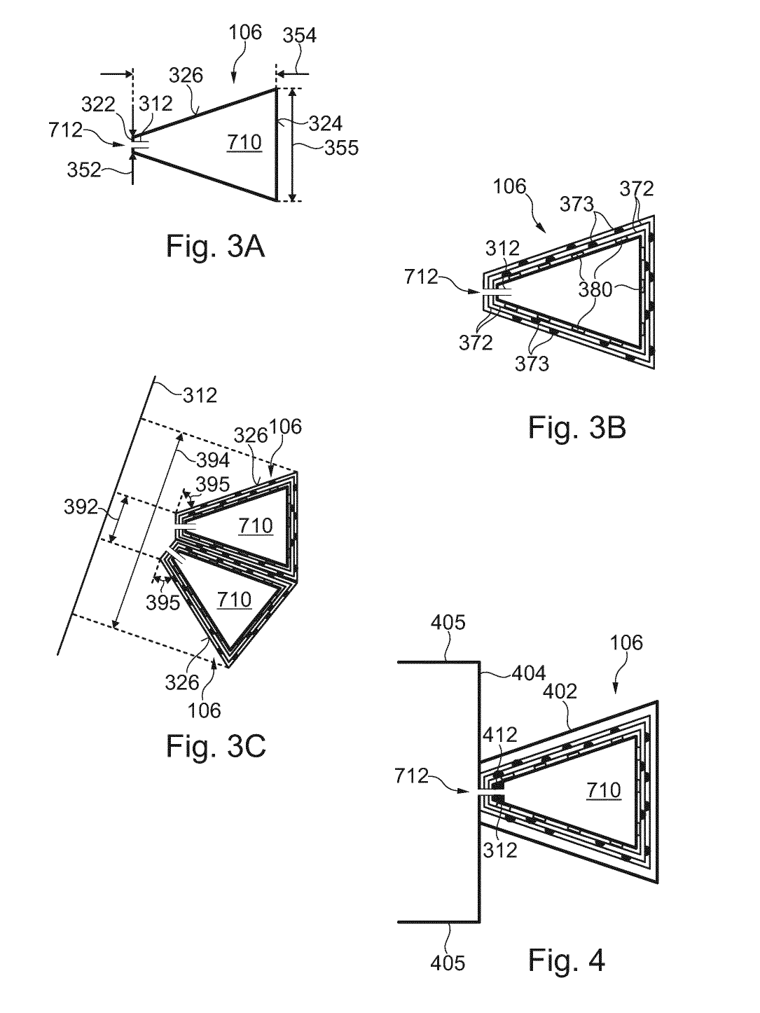

As described herein, the distribution pipe can be a hollow cylinder. Thereby, the term cylinder can be understood as commonly accepted as having a circular bottom shape and a circular upper shape and a curved surface area or shell connecting the upper circle and the little lower circle. Thereby, embodiments described herein provide for a reduced heat transfer to the mask by heat shields and cooling shield arrangements. For example, the heat transfer from the evaporation source to the mask can be reduced by having nozzles penetrating through the heat shields and the cooling shield arrangements. According to further additional or alternative embodiments, which can be combined with other embodiments described herein, the term cylinder can further be understood in the mathematical sense as having an arbitrary bottom shape and an identical upper shape and a curved surface area or shell connecting the upper shape and the lower shape. Accordingly, the cylinder does not necessarily need to have a circular cross-section. Instead, the base surface and the upper surface can have a shape different from a circle. Specifically, the cross-section can have a shape as will be described in more detail with respect to FIGS. 3A to 4 and 6A to 8B.

FIG. 3A shows a cross-section of a distribution pipe 106. The distribution pipe 106 has walls 322, 326, and 324, which surround an inner hollow space 710. The wall 322 is provided at an outlet side of the evaporation crucible, at which the outlets 712 are provided. According to some embodiments, which can be combined with other embodiments described herein, and outlet 712 can be provided by the nozzle 312. The cross-section of the distribution pipe can be described as being essentially triangular, that is the main section of the distribution pipe corresponds to a portion of a triangle and/or the cross-section of the distribution pipe can be triangular with rounded corners and/or cut-off corners. As shown in FIG. 3A, for example the corner of the triangle at the outlet side is cut off.

The width of the outlet side of the distribution pipe, e.g. the dimension of the wall 322 in the cross-section shown in FIG. 3A, is indicated by arrow 352. Further, the other dimensions of the cross-section of the distribution pipe 106 are indicated by arrows 354 and 355. According to embodiments described herein, the width of the outlet side of the distribution pipe is 30% or less of the maximum dimension of the cross-section, e.g. 30% of the larger dimension of the dimensions indicated by arrows 354 and 355. In light thereof, outlet 712 of neighboring distribution pipes 106 can be provided at a smaller distance. The smaller distance improves mixing of organic materials, which are evaporated next to each other. This can be better understood when referring to FIGS. 3C, 6A, 6B, and 7. Yet further, additionally or alternatively, and independent of the improved mixing of organic materials, the width of the wall facing the deposition area, or substrate respectively, in an essentially parallel manner, can be reduced. Correspondingly, the surface area of a wall facing a deposition area, or substrate respectively, in an essentially parallel manner, e.g. wall 322, can be reduced. This reduces the heat load provided to a mask or substrate, which are supported in the deposition area or slightly before the deposition area.

According to some embodiments, which can be combined with other embodiments described herein, the product of the length of the distribution pipe and the area of all outlets in the distribution pipe divided by the hydraulic diameter of the distribution pipe, i.e. the value calculated by the formula N*A*L/D, can be 7000 mm² or below, for example 1000 mm² to 5000 mm². Thereby, N is the number of outlets in the distribution pipe, A is the cross-section area of one outlet, L is the length of the distribution pipe, and D is the hydraulic diameter of the distribution pipe.

FIG. 3B illustrates further details of the distribution pipe 106 according to some embodiments described herein. One or more heating elements 380 are provided at the walls surrounding the inner hollow space 710. The heating devices can be electrical heaters which are mounted to the walls of the distribution pipe. For example, the heating devices can be provided by heating wires, e.g. coated heating wires, which are clamped or otherwise fixed to the distribution pipe 106.

Two or more heat shields 372 are provided around the one or more heating elements 380. For example, the heat shields 372 can be spaced apart from each other. Protrusions 373, which can be provided as spots on one of the heat shields, separate the heat shields with respect to each other. Accordingly, a stack of heat shields 372 is provided. For example, two or more heat shields, such as five or more heat shields or even 10 heat shields can be provided. According to some embodiments, this stack is designed in a way that compensates for the thermal expansion of the source during the process, so that the nozzles are never blocked. According to yet further embodiments, which can be combined with other embodiments described herein, the outermost shield can be water-cooled.

As exemplarily shown in FIG. 3B, the outlet 712, which is shown in the cross-section shown in FIG. 3B, is provided with a nozzle 312. The nozzle 312 extends through the heat shields 372. This can reduce condensation of organic material at the heat shields, as the nozzle guides the organic material through this stack of heat shields. The nozzle can be heated to a temperature, which is similar to the temperature inside the distribution pipe 106. In order to improve heating of the nozzle 312, a nozzle support portion 412 can be provided, which is in contact with the heated walls of the distribution pipe, as for example shown in FIG. 4.

FIG. 3C shows an embodiment, where two distribution pipes are provided next to each other. Accordingly, an evaporation source having a distribution pipe arrangement as shown in FIG. 3C can evaporate two organic materials next to each other. Such an evaporation source can thus also be referred to as an evaporation source array. As shown in FIG. 3C, the shape of the cross-section of the distribution pipes 106 allow to place the outlets or nozzles of neighboring distribution pipes close to each other. According to some embodiments, which can be combined with other embodiments described herein, a first outlet or nozzle of the first distribution pipe and a second outlet or nozzle of the second distribution pipe can have a distance of 25 mm or below, such as from 5 mm to 25 mm. More specifically, the distance of the first outlet or nozzle to a second outlet or nozzle can be 10 mm or below.

According to yet further embodiments, which can be combined with other embodiments described herein, tube extensions of the nozzles 312 can be provided. In light of the small distance between the distribution pipes, such tube extensions can be sufficiently small to avoid clogging or condensation therein. Tube extensions can be designed such that nozzles of two or even three sources can be provided in one line above each other, i.e. in one line along the extension of the distribution pipe, which can be a vertical extension. With this special design it is even possible to arrange the nozzles of the two or three sources in one line over small tube extensions, so that a perfect mixing is achieved.

FIG. 3C further illustrates the reduced heat load according to embodiments described herein. A deposition area 312 is shown in FIG. 3C. Typically a substrate can be provided in the deposition area for deposition of organic material on a substrate. The angle 395 between the sidewall 326 and the deposition area 312 is indicated in FIG. 3C. As can be seen, the sidewall 326 is inclined by a comparably large angle such that the heat radiation, which might occur in spite of the heat shields and cooling elements is not directly radiated towards the deposition area. According to some embodiments, which can be combined with other embodiments described herein, the angle 395 can be 15° or more. Accordingly, the dimension or area, which is indicated by arrow 392, is significantly smaller as compared to the dimension or area, which is indicated by arrow 394. Thereby, the dimension indicated by arrow 392 corresponds to the dimension of the cross-section of the distribution pipes 106, for which the surface facing the deposition area is essentially parallel or has an angle of 30° or less or even 15° or less. The corresponding area, i.e. the area which provides direct heat load to the substrate, is the dimension shown in FIG. 3C multiplied with the length of the distribution pipes. The dimension indicated by arrow 394 is a projection on the deposition area 312 of the entire evaporation source in the respective cross-section. The corresponding area, i.e. the area of the projection onto the surface of the deposition area, is the dimension (arrow 394) shown in FIG. 3C multiplied with the length of the distribution pipes. According to embodiments described herein, which can be combined with other embodiments described herein, the area indicated by arrow 392 can be 30% or less as compared to the area indicated by arrow 394. In light of the above, the shape of the distribution pipes 106 reduces the direct heat load radiated towards the deposition area. Accordingly, temperature stability of the substrate and a mask provided in front of the substrate can be improved.

FIG. 4 illustrates yet further optional modifications of evaporation sources according to embodiments described herein. FIG. 4 shows a cross-section of a distribution pipe 106. Walls of the distribution pipe 106 surround the inner hollow space 710. Vapor can exit the hollow space through nozzle 312. In order to improve heating of the nozzle 312, a nozzle support 412 is provided, which is in contact with the heated walls of the distribution pipe 106. The outer shield 402, which surrounds the distribution pipe 106 is a cooled shield for further reducing the heat load. Further, a cooled shield 404 is provided to additionally reduce the heat load directed towards the deposition area or a substrate, respectively.

According to some embodiments, which can be combined with other embodiments described herein, the cooled shields can be provided as metal plates having conduits for cooling fluid, such as water, attached thereto or provided therein. Additionally, or alternatively, thermoelectric cooling means or other cooling means can be provided to cool the cooled shields. Typically, the outer shields, i.e. the outermost shields surrounding the inner hollow space of a distribution pipe, can be cooled.

FIG. 4 illustrates a further aspect, which can be provided according to some embodiments. Shaper shields 405 are shown in FIG. 4. The shaper shields typically extend from a portion of the evaporation source towards the substrate or the deposition area. Accordingly, the direction of the vapor existing the distribution pipe or pipes through the outlets can be controlled, i.e. the angle of the vapor emission can be reduced. According to some embodiments, at least a portion of the organic material evaporated through the outlets or nozzles is blocked by the shaper shield. Thereby, the width of the emission angle can be controlled. According to some implementations, the shaper shields 405 can be cooled similar to the cooled shields 402 and 402 in order to further reduce the heat radiation emitted towards the deposition area.

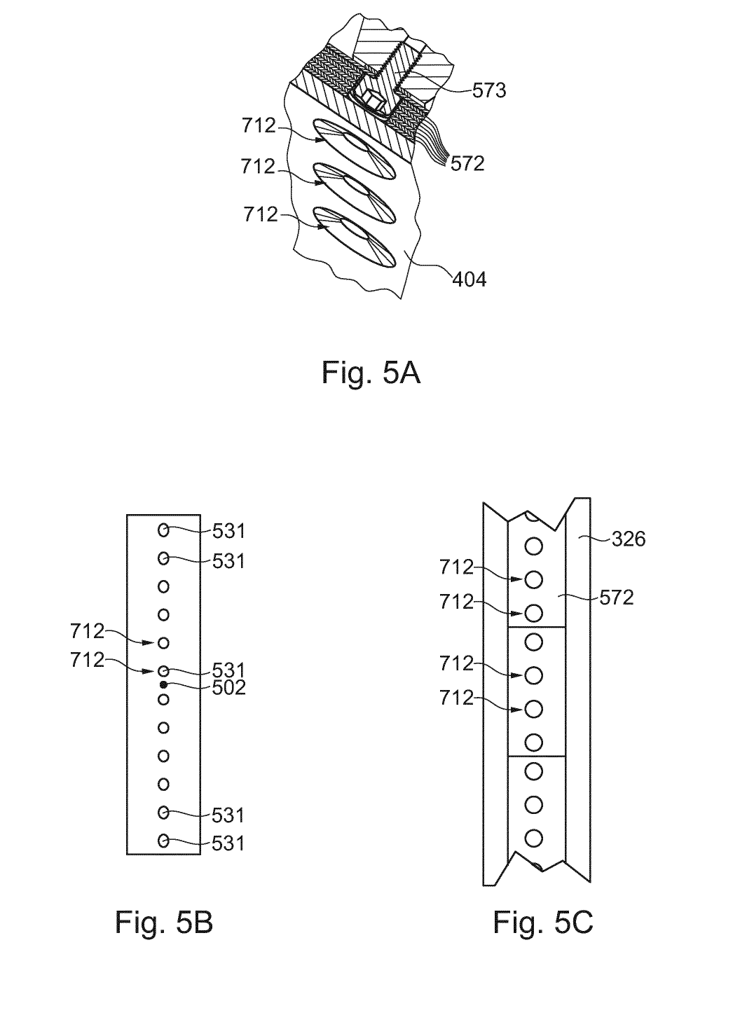

FIG. 5A shows a portion of an evaporation source. According to some embodiments, which can be combined with other embodiments described herein, the evaporation source or the evaporation source array is a vertical linear source. Accordingly, the three outlets 712 are a portion of a vertical outlet array. FIG. 5A illustrates a stack of heat shields 572, which can be attached to the distribution pipe by fixation element 573, e.g. a 3screw or the like. Further, the outer shield 404 is a cooled shield having further openings provided therein. According to some embodiments, which can be combined with other embodiments described herein, the design of the outer shield can be configured to allow for thermal extension of the components of the evaporation source, wherein the openings maintain alignment with the nozzles of the distribution pipe or reach alignment with the nozzles of the distribution pipe when the operation temperature is reached. FIG. 5B shows a side view of a cooled outer shield 404. The cooled outer shield can essentially extend along the length of the distribution pipe. Alternatively, two or three cooled outer shields can be provided next to each other to extend along the length of the distribution pipe. The cooled outer shield is attached to the evaporation source by fixation element 502, e.g. a screw, wherein the fixation element is provided essentially in the center (±10% or ±20%) of the distribution pipe along the length extension. Upon thermal expansion of the distribution pipe the length of the portion of the outer shield 404, which is subject to thermal extension is reduced. The openings 531 in the outer shield 404 can be circular close to the fixation element 532 and can have an oval shape at a larger distance to the fixation element.

According to some embodiments, the length of the openings 531 in a direction parallel to the longitudinal axis of the evaporation pipe can be increased the larger the distance from the fixation element is. Typically, the width of the openings 531 in a direction perpendicular to the longitudinal axis of the evaporation pipe can be constant. In light of the above, the outer shield 404 can extend upon thermal expansion particularly along the longitudinal axis of the evaporation pipe and the increased dimension parallel to the longitudinal axis of the evaporation pipe can compensate or at least partially for the thermal expansion. Accordingly, the evaporation source can be operated in a wide temperature range without the openings in the outer shield 404 blocking the nozzles.

FIG. 5C illustrates a further optional feature of embodiments described herein, which can likewise also be provided for other embodiments described herein. FIG. 5C shows a side view from the side of wall 322 (see FIG. 3A), wherein a shield 572 is provided at the wall 322. Further, the side wall 326 is shown in FIG. 5C. As can be seen in FIG. 5C the shield 572 or the shields in the stack of shields are segmented along the length of the evaporation pipe. Thereby, the length of shield portion can be 200 mm or below, e.g. 120 mm or below, such as 60 mm to 100 mm. Accordingly, the length of the shield portions, e.g. the stack of shields is reduced in order to reduce thermal expansion thereof. Accordingly, the alignment of the openings in the shield, through which the nozzles can extend and which correspond to the outlets 712, is less critical.

According to yet further embodiments, which can be combined with other embodiments described herein, two or more heat shields 372 are provided around the inner hollow space 710 and the heated portion of the distribution pipe 106. Accordingly, the heat radiation towards the substrate, the mask or another portion of a deposition apparatus from the heated portion of the distribution pipe 106 can be reduced. According to one example, as shown in FIG. 5, more layers of heat shields 572 can be provided at the side at which the openings or outlets are provided. A stack of heat shields is provided. According to typical embodiments, which can be combined with other embodiments described herein, the heat shields 372 and/or 572 are spaced apart from each other, for example by 0.1 mm to 3 mm. According to some embodiments, which can be combined with other embodiments described herein, the stack of heat shields is designed as described with respect to FIGS. 5A to 5C such that compensates for the thermal expansion of the source during the process, so that the nozzles are never blocked. Additionally the outermost shield can be cooled, e.g. water cooled. Thus, according to some embodiments, an outer shield 404, particularly at the side at which the openings are provided, can be a cooled shield, e.g. having cone shaped openings provided therein. Accordingly, such an arrangement allows for a temperature stability with a deviation of ΔT of 1° C. even if the nozzles have a temperature of about 400° C.

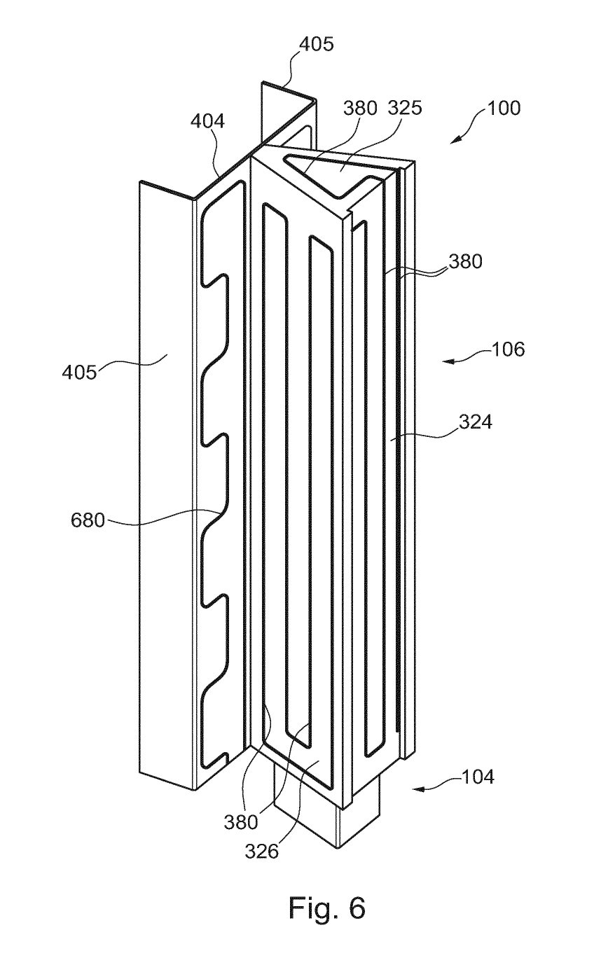

FIG. 6 shows a further view of an evaporation source 100. An evaporation crucible 104 is provided for evaporating the organic material. A heating element (not shown in FIG. 6) is provided for heating the evaporation crucible 104. The distribution pipe 106 is in fluid communication with the evaporation crucible, such that organic material evaporated in the evaporation crucible can be distributed in the distribution pipe 106. The evaporated organic material exits the distribution pipe 106 through openings (not shown in FIG. 6.) The evaporation crucible 106 has sidewalls 326, a wall 324 opposing the wall at the outlet side and a top wall 325. The walls are heated by heating element 380, which are mounted or attached to the walls. According to some embodiments, which can be combined with other embodiments described herein, the evaporation source and/or one or more of the walls respectively, can be made of quartz or titanium. Specifically, the evaporation source and/or one or more of the walls can be made of titanium. Both sections, the evaporation crucible 104 and the distribution pipe 106, can be heated independently from each other.

Shield 404, which further reduces the heat radiation towards the deposition area, is cooled by cooling element 680. For example, conduits for having a cooling fluid provided therein can be mounted to the shield 404. As shown in FIG. 6, additionally shaper shields 405 can be provided at the cooling shield 404. According to some embodiments, which can be combined with other embodiments described herein, the shaper shield can also be cooled, e.g. water cooled. For example, the shaper shield can be attached to the cooling shield or cooling shield arrangement. The thickness uniformity of the deposited film of organic material can be tuned over the nozzle array and additional shaper shields, which can be placed aside of the one or more outlets or nozzles. The compact design of the source allows for moving the source with a driving mechanism in a vacuum chamber of a deposition apparatus. In this case all controllers, power supplies and additional support functions are implemented in an atmospheric box, which is attached to the source.

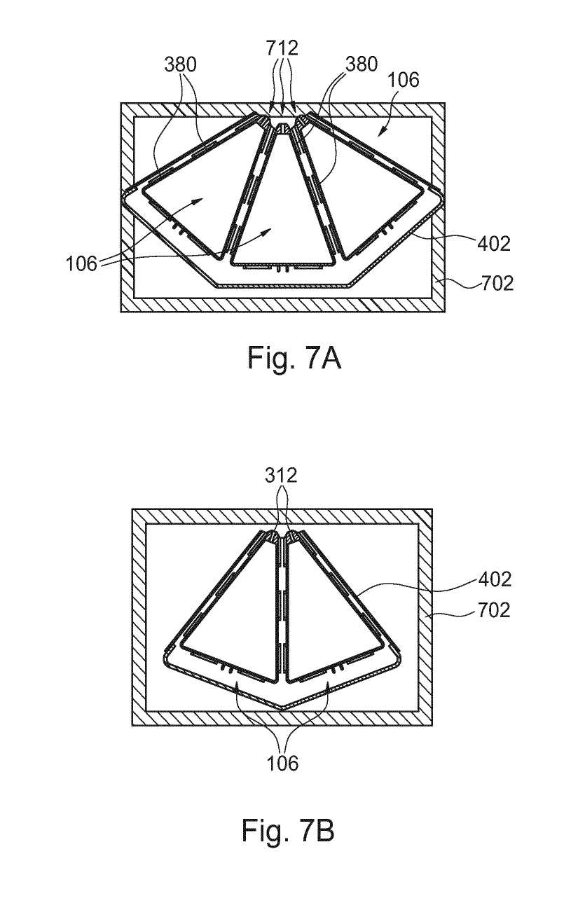

FIGS. 7A and/B show further top views including a cross-section of distribution pipes 106. FIG. 7A shows an embodiment having three distribution pipes 706, which are provided over an evaporator control housing 702. The evaporator control housing is configured to maintain atmospheric pressure therein and is configured to house at least one element selected from the group consisting of: a switch, a valve, a controller, a cooling unit, a cooling control unit, a heating control unit, a power supply, and a measurement device. Accordingly, a component for operating the evaporation source for the evaporation source array can be provided under atmospheric pressure close to the evaporation crucible and the distribution pipe and can be moved through the deposition apparatus together with the evaporation source.

The distribution pipes 106 shown in FIG. 7A are heated by heating element 380. A cooled shield 402 is provided surrounding the distribution pipes 106. According to some embodiments, which can be combined with other embodiments described herein, one cooled shield can surround two or more distribution pipes 106. The organic materials, which are evaporated in an evaporation crucible are distributed in a respective one of the distribution pipes 106 and can exit the distribution pipe through outlets 712. Typically, a plurality of outlets are distributed along the length of the distribution pipe 106. FIG. 7B shows an embodiment similar to FIG. 7A, wherein two distribution pipes are provided. The outlets are provided by nozzles 312. Each distribution pipe is in fluid communication with the evaporation crucible (not shown in FIGS. 7A and 7B), and wherein the distribution pipe has a cross-section perpendicular to the length of the distribution pipe, which is non-circular, and which includes an outlet side at which the one or more outlets are provided, wherein the width of the outlet side of the cross-section is 30% or less of the maximum dimension of the cross-section.

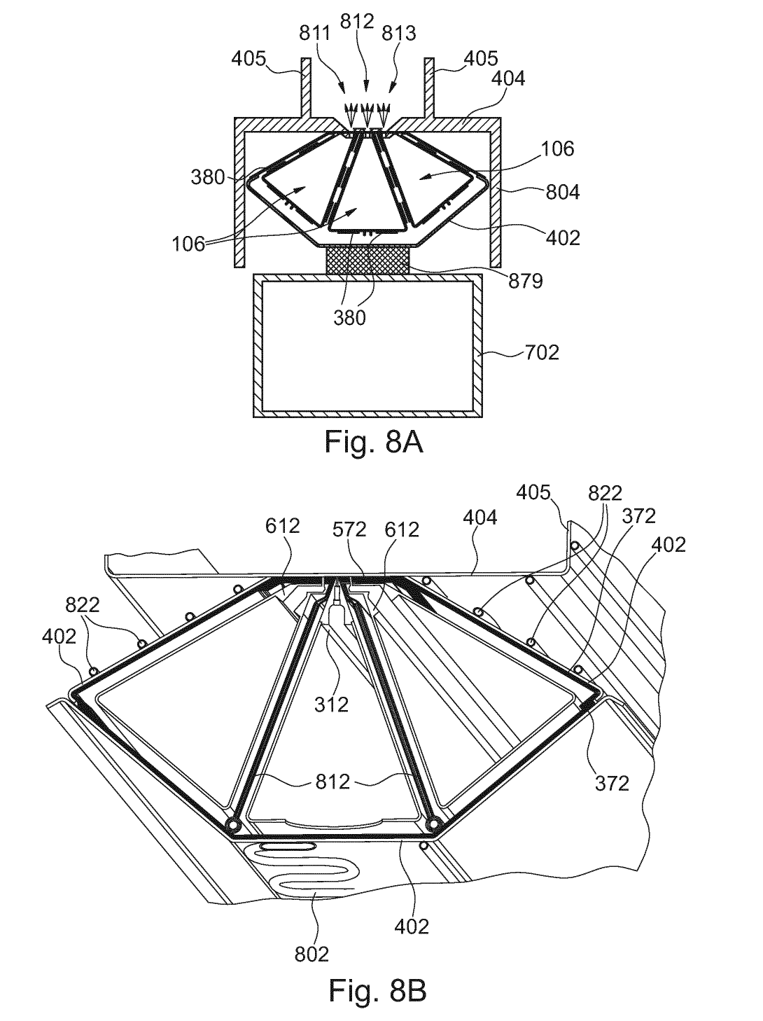

FIG. 8A illustrates yet further embodiments described herein. Three distribution pipes 106 are provided. An evaporator control housing 702 is provided adjacent to the distribution pipes and connected thereto via a thermal insulator 879. As described above, the evaporator control housing, configured to maintain atmospheric pressure therein, is configured to house at least one element selected from the group consisting of: a switch, a valve, a controller, a cooling unit, a cooling control unit, a heating control unit, a power supply, and a measurement device. In addition to the cooled shield 402, the cooled shield 404 is provided, which has sidewalls 804. The cooled shield 404 and the sidewalls 804 provide a U-shaped cooled heat shield to reduce the heat radiation towards the deposition area, i.e. a substrate and/or a mask. Arrows 811, 812, and 813, respectively illustrate evaporated organic material exiting distribution pipes 106. Due to the essentially triangular shape of the distribution pipes, the evaporation cones originating from the three distribution pipes are in close proximity to each other, such that mixing of the organic materials from the different distribution pipes can be improved.

As further shown in FIG. 8A, shaper shields 405 are provided, for example, attached to the cooled shield 404 or as a part of the cooled shield 404. According to some embodiments, the shaper shields 405 can also be cooled to further reduce the heat load emitted towards the deposition area. The shaper shields delimit the distribution cone of the organic materials distributed towards the substrates, i.e. the shaper shields are configured to block at least a portion of the organic materials.

FIG. 8B shows a cross-sectional view of yet another evaporation source according to embodiments described herein. Three distribution pipes are shown, wherein each distribution pipes are heated by heating elements (not shown in FIG. 8A). The vapor generated in evaporation crucibles (not shown) exit the distribution pipe through nozzles 312 and 512 respectively. In order to have the outlets 712 of the nozzles closer together, the outer nozzles 512 include tube extensions, which include short tubes extending towards the nozzle tubes of the center distribution pipe. Thereby, according to some embodiments, the tube extensions 512 can have a bend such as a 60° to 120° bend, e.g. a 90° bend. A plurality of shields 572 are provided at the outlet sidewall of the evaporation source. For example, at least 5 or even at least 7 shields 572 are provided at the outlet side of the evaporation tube. A shield 402 is provided the one or more distribution pipe, wherein cooling elements 822 are provided. Between the distribution pipe and the shield 402 a plurality of shields 372 are provided. For example, at least 2 or even at least 5 shields 372 are provided between the distribution pipe and the shield 402. The plurality of shields 572 and the plurality of shields 372 are provided as stacks of shields, e.g. wherein the shields are distant from each other by 0.1 mm to 3 mm.

According to yet further embodiments, which can be combined with other embodiments described herein, a further shield 812 can be provided between the distribution pipes. For example, the further shield 812 can be a cooled shield or a cooled lug. Thereby, the temperature of the distribution pipes can be controlled independent from each other. For example, in the event different materials are evaporated through neighboring distribution pipes (such as a host and a dopant), these materials may need to be evaporated at different temperatures. Accordingly, the further shield 812, e.g. a cooled shield, can reduce cross-talk between the distribution pipes in an evaporation source or an evaporation source array.

The embodiments described herein mostly relate to evaporation sources and evaporation apparatuses for depositing organic material on a substrate, while the substrate is essentially vertically oriented. The essentially vertical substrate orientation allows for a small footprint of deposition apparatuses and specifically deposition systems including several deposition apparatuses for coating several layers of organic material on a substrate. Thereby, it can be considered that apparatuses described herein are configured for large area substrate processing or processing of a plurality of substrates in large area carriers. The vertical orientation further allows for a good scalability for current and future substrate size generations, that is present and future glass sizes. Yet, the evaporation sources with the improved cross sectional shape and the concept of heat shields and cooling elements can also be provided for material deposition on horizontal substrates.

FIGS. 9A and 9B show a yet further embodiment of deposition apparatus 500. FIG. 9A shows a schematic top view of the deposition apparatus 500. FIG. 9B shows a schematic cross-sectional side view of the deposition apparatus 500. The deposition apparatus 500 includes a vacuum chamber 110. The valve 205, for example a gate valve, allows for a vacuum seal to an adjacent vacuum chamber. The valve can be open for transport of a substrate 121 or a mask 132 into the vacuum chamber 110 or out of the vacuum chamber 110. Two or more evaporation sources 100 are provided in the vacuum chamber 110. The example shown in FIG. 9A shows seven evaporation sources. According to typical embodiments, which can be combined with other embodiments described herein, to evaporation sources, three evaporation sources, or four evaporation sources can beneficially be provided. As compared to a higher number of evaporation sources, which may also be provided according to some embodiments, the logistics of maintenance of the limited number of evaporation sources (e.g. 2 to 4) might be easier. Accordingly, the cost of ownership might be better for such systems.

According to some embodiments, which can be combined with other embodiments described herein, and as for example shown in FIG. 9A, the looped track 530 can be provided. The looped track 530 can include straight portions 534 and curved portions 533. The looped track 530 provides for a translational movement of the evaporation sources and the rotation of the evaporation sources. As described above, the evaporation sources can typically be line sources, e.g. linear vapor distribution showerheads.

According to some embodiments, which can be combined with other embodiments described herein, the looped track includes a rail or a rail arrangement, a roller arrangement or a magnetic guide to move the one or more evaporation sources along the looped track.

Based upon the looped track 530, a train of sources can move with translational movement along a substrate 121, which is typically masked by a mask 132. The curved portion 533 of the looped track 530 provides a rotation of the evaporation source 100. Further, the curved portion 533 can provide for positioning the evaporation source in front of a second substrate 121. The further straight portion 534 of the looped track 530 provides a further translational movement along the further substrate 121. Thereby, as mentioned above, according to some embodiments, which can be combined with other embodiments described herein, the substrates 121 and the masks 132 remain essentially stationary during deposition. The evaporation sources providing line sources, e.g. line sources with an essentially vertical orientation of the line, are moved along the stationary substrates.

According to some embodiments, which can be combined with other embodiments described herein, a substrate 121 shown in vacuum chamber 110 can be supported by a substrate support having rollers 403 and 424 and further, in a stationary deposition position, by a substrate support 126, which are connected to alignment units 112. An alignment unit 112 can adjust the position of the substrate 121 with respect to the mask 132. Accordingly, the substrate can be moved relative to the mask 132 in order to provide for a proper alignment between the substrate and the mask during deposition of the organic material. According to a further embodiment, which can be combined with other embodiments described herein, alternatively or additionally the mask 132 and/or the mask frame 131 holding the mask 132 can be connected to the alignment unit 112. Thereby, either the mask can be positioned relative to the substrate 121 or the mask 132 and the substrate 121 can both be positioned relative to each other.

The embodiment shown in FIGS. 9A and 9B shows two substrates 121 provided in the vacuum chamber 110. Yet, particularly for embodiments including a train of evaporation sources 100 in a vacuum chamber at least three substrates or at least four substrates can be provided. Thereby, sufficient time for exchange of the substrate, i.e. transport of a new substrate into the vacuum chamber and of a processed substrate out of the vacuum chamber, can be provided even for a deposition apparatus 500 having a larger number of evaporation sources and, thus, a higher throughput.

FIGS. 9A and 9B show the first transportation track for a first substrate 121 and a second transportation track for a second substrate 121. A first roller assembly is shown on one side of the vacuum chamber 110. The first roller assembly includes rollers 424. Further, the transportation system includes a magnetic guiding element 524. Similarly, a second transportation system having rollers and a magnetic guiding element is provided on the opposing side of the vacuum chamber. The upper portions of the carriers 421 are guided by magnetic guiding elements 524. Similarly, according to some embodiments, the mask frames 131 can be supported by rollers 403 and magnetic guiding elements 503.

FIG. 9B exemplarily shows two supports 102 provided on a respective straight portion 534 of the looped track 530. Evaporation crucibles 104 and distribution pipes 106 are supported by the respective supports 102. Thereby, FIG. 5B illustrates two distribution pipes 106 supported by a support 102. The supports 102 are shown as being guided on the straight portions 534 of the looped track. According to some embodiments, which can be combined with other embodiments described herein, an actuator, a drive, a motor, a drive belt, and/or a drive chain can be provided to move the support 102 to along the looped track, i.e. along the straight portions 534 of the looped track and along the curved portion 533 (see FIG. 9A) of the looped track.

According to embodiments of deposition apparatuses described herein, a combination of the translational movement of a line source, e.g. a linear vapor distribution showerhead, and the rotation of the line source, e.g. a linear vapor distribution showerhead, allows for a high evaporation source efficiency and a high material utilization for OLED display manufacturing, wherein a high precision of masking of the substrate is desired. A translational movement of the source allows for a high masking precision since the substrate and the mask can maintain stationary. The rotational movement allows for a substrate exchange of one substrate while another substrate is coated with organic material. This significantly improves the material utilization as the idle time, i.e. the time during which the evaporation source evaporates organic material without coating a substrate, is significantly reduced.

Embodiments described herein particularly relate to deposition of organic materials, e.g. for OLED display manufacturing and on large area substrates. According to some embodiments, large area substrates or carriers supporting one or more substrates, i.e. large area carriers, may have a size of at least 0.174 m². Typically, the size of the carrier can be about 1.4 m² to about 8 m², more typically about 2 m² to about 9 m² or even up to 12 m². Typically, the rectangular area, in which the substrates are supported, for which the holding arrangements, apparatuses, and methods according to embodiments described herein are provided, are carriers having sizes for large area substrates as described herein. For instance, a large area carrier, which would correspond to an area of a single large area substrate, can be GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. According to typical embodiments, which can be combined with other embodiments described herein, the substrate thickness can be from 0.1 to 1.8 mm and the holding arrangement, and particularly the holding devices, can be adapted for such substrate thicknesses. However, particularly the substrate thickness can be about 0.9 mm or below, such as 0.5 mm or 0.3 mm, and the holding arrangement, and particularly the holding devices, are adapted for such substrate thicknesses. Typically, the substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

In order to achieve good reliability and yield rates, embodiments described herein keep the mask and substrate stationary during the deposition of organic material. A movable linear source for uniform coating of a large area substrate is provided. The idle time is reduced as compared to an operation wherein after each deposition the substrate needs to be exchanged including a new alignment step of the mask and the substrate relative to each other. During the idle time, the source is wasting material. Accordingly, having a second substrate in a deposition position and readily aligned with respect to the mask reduces the idle time and increases the material utilization.

The embodiments described herein further provide evaporation sources (or evaporation source arrays) having a reduced heat radiation towards the deposition area, i.e. substrate and/or a mask such that the mask can be held at an essentially constant temperature which is within the temperature range of 5° C. or below or even within a temperature range of 1° C. or below. Yet further, the shape of the distribution pipe or distribution pipes with the small width at the outlet side reduces the heat load on the mask and further improves mixing of different organic materials because the outlets of neighboring distribution pipes can be provided in close proximity, e.g. at a distance of 25 mm or below.

According to typical embodiments, which can be combined with other embodiments described herein, an evaporation source includes at least one evaporation crucible, and at least one distribution pipe, e.g. at least one linear vapor distribution showerhead. However, an evaporation source can include two or three, eventually even four or five evaporation crucibles and corresponding distribution pipes. Thereby, different organic materials can be evaporated in at least two of the several crucibles, such that the different organic materials form one organic layer on the substrate. Additionally or alternatively, similar organic materials can be evaporated in at least two of the several crucibles, such that the deposition rate can be increased. This is particularly true as organic materials can often only be evaporated in a relatively small temperature range (e.g. 20° C. or even below) and the evaporation rate can, thus, not be greatly increased by increasing the temperature in the crucible.

According to embodiments described herein, the evaporation sources, the deposition apparatuses, the methods of operating evaporation sources and/or deposition apparatuses, and the methods of manufacturing evaporation sources and/or deposition apparatuses are configured for a vertical deposition, i.e. the substrate is supported in an essentially vertical orientation (e.g. vertical+−10°), during layer deposition. Further, a combination of a line source, a translational movement and a rotation of the evaporation direction, particularly a rotation around an axis being essentially vertical, e.g. parallel to the substrate orientation and/or the direction of the line-extension of the line source, allows for a high material utilization of about 80% or above. This is an improvement of at least 30% as compared to other systems.

A movable and turnable evaporation source within the process chamber, i.e. the vacuum chamber for layer deposition therein, allows for a continuous or almost continuous coating with high material utilization. Generally, embodiments described herein allow for a high evaporation source efficiency (>85%) and a high material utilization (at least 50% or above) by using a scanning source approach with 180° turning mechanism to coat two substrates alternating. Thereby, the source efficiency takes into consideration material losses occurring due to the fact that the vapor beams extend over the size of the large area substrates in order to allow for a uniform coating of the entire area of the substrate which is to be coated. The material utilization additionally considers losses occurring during idle times of the evaporation source, i.e. times where the evaporation source cannot deposit the evaporated material on a substrate.

Yet further, the embodiments described herein and relating to a vertical substrate orientation allow for a small footprint of deposition apparatuses and specifically deposition systems including several deposition apparatuses for coating several layers of organic material on a substrate. Thereby, it can be considered that apparatuses described herein are configured for large area substrate processing or processing of a plurality of substrates in large area carriers. The vertical orientation further allows for a good scalability for current and future substrate size generations, that is present and future glass sizes.

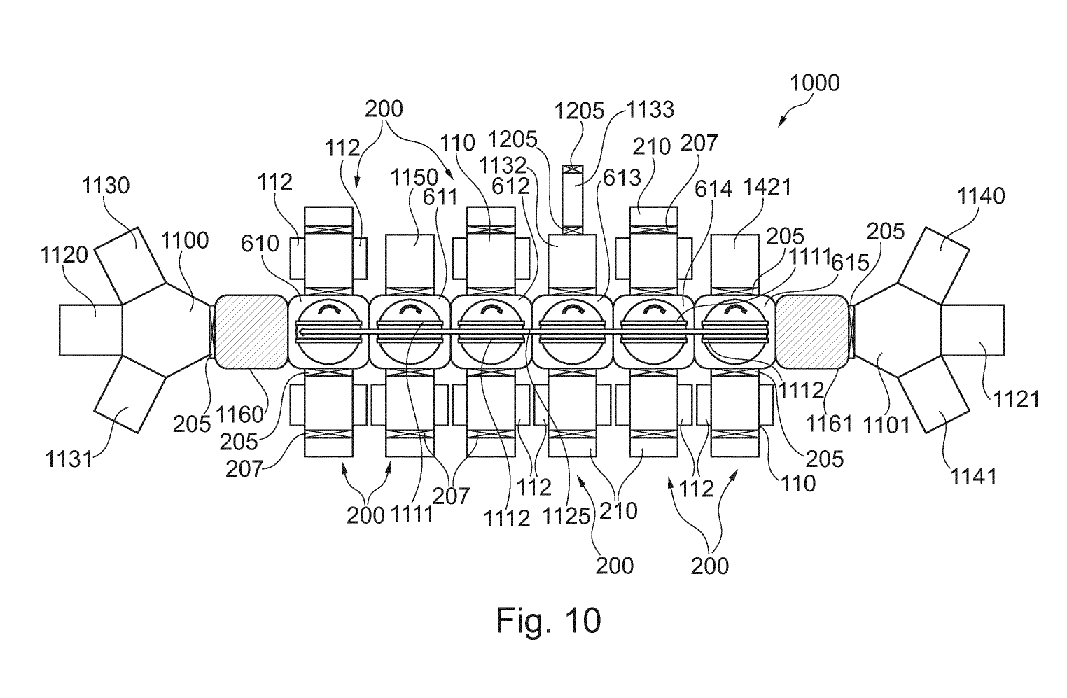

FIG. 10 shows a system 1000 for manufacturing devices, particularly devices including organic materials therein. For example, the devices can be electronic devices or semiconductor devices, such as optoelectronic devices and particularly displays. Evaporation sources as described herein can beneficially be utilized in a system as described with respect to FIG. 10. An improved carrier handling and/or mask handling of a mass production system can be provided by a system 1000. According to typical embodiments, which can be combined with other embodiments described herein, these improvements can be beneficially utilized for OLED device manufacturing and can, thus, include evaporation sources, deposition apparatuses, components thereof, as described with respect to FIGS. 1 to 9B. Embodiments described herein particularly relate to deposition of materials, e.g. for display manufacturing and on large area substrates. According to some embodiments, large area substrates or carriers supporting one or more substrates, i.e. large area carriers, may have a size of at least 0.174 m². Typically, the size of the carrier can be about 1.4 m² to about 8 m², more typically about 2 m² to about 9 m² or even up to 12 m². Typically, the rectangular area, in which the substrates are supported and for which the holding arrangements, apparatuses, and methods according to embodiments described herein are provided, are carriers having sizes for large area substrates as described herein. For instance, a large area carrier, which would correspond to an area of a single large area substrate, can be GEN 5, which corresponds to about 1.4 m² substrates (1.1 m×1.3 m), GEN 7.5, which corresponds to about 4.29 m² substrates (1.95 m×2.2 m), GEN 8.5, which corresponds to about 5.7 m² substrates (2.2 m×2.5 m), or even GEN 10, which corresponds to about 8.7 m² substrates (2.85 m×3.05 m). Even larger generations such as GEN 11 and GEN 12 and corresponding substrate areas can similarly be implemented. According to typical embodiments, which can be combined with other embodiments described herein, the substrate thickness can be from 0.1 to 1.8 mm and the holding arrangement, and particularly the holding devices, can be adapted for such substrate thicknesses. However, particularly the substrate thickness can be about 0.9 mm or below, such as 0.5 mm or 0.3 mm, and the holding arrangement, and particularly the holding devices, are adapted for such substrate thicknesses. Typically, the substrate may be made from any material suitable for material deposition. For instance, the substrate may be made from a material selected from the group consisting of glass (for instance soda-lime glass, borosilicate glass etc.), metal, polymer, ceramic, compound materials, carbon fiber materials or any other material or combination of materials which can be coated by a deposition process.

The coater or deposition system concepts, e.g. for OLED mass production according to some embodiments, provides a vertical cluster approach, such that for example “random” access to all chamber may be provided. Accordingly, such concepts are efficient for both RGB and White on CF (color filter) deposition by offering flexibility in adding a desired number of modules required. This flexibility could also be used to create redundancy. Generally, for OLED display manufacturing two concepts can be provided. On the one hand, RGB (red green blue) displays having emission of red light, green light, and blue light are manufactured. On the other hand, White on CF displays are manufactured, wherein white light is emitted and colors are generated by a color filter. Even though White on CF displays requires a reduced number of chambers for manufacturing such a device, both concepts are in practice and have their pros and cons.

According to embodiments described herein, which can be combined with other embodiments described herein, OLED device manufacturing typically includes masking of the substrates for deposition. Further, the large area substrates are typically supported by a carrier during processing thereof. Both mask handling and carrier handling can be critical particularly for OLED devices with respect to temperature stability, cleanliness of mask and carrier and the like. Accordingly, embodiments described herein provide a carrier return path under vacuum conditions or under a defined gas atmosphere, e.g. a protective gas, and improved cleaning options for carriers and masks.

According to yet further embodiments, which can be combined with other embodiments described herein, mask cleaning can be provided either in-situ, for example by an optional plasma cleaning or can be provided by offering a mask exchange interface to allow for external mask cleaning without venting processing chambers or transfer chambers of the manufacturing system.

The manufacturing system 1000 shown in FIG. 10 includes a load lock chamber 1120, which is connected to a horizontal substrate handling chamber 1100. The substrate can be transferred from the glass handling chamber 1102 to a vacuum swing module 1160, wherein the substrate is loaded in a horizontal position on a carrier. After loading the substrate on the carrier in the horizontal position, the vacuum swing module 1160 rotates the carrier having the substrate provided thereon in a vertical or essentially vertical orientation. The carrier having the substrate provided thereon is then transferred through a first transfer chamber 610 and at least one further transfer chamber (611-615) having the vertical orientation. One or more deposition apparatuses 200 can be connected to the transfer chambers. Further, other substrate processing chambers or other vacuum chambers can be connected to one or more of the transfer chambers. After processing of the substrate, the carrier having a substrate thereon is transferred from the transfer chamber 615 into a further vacuum swing module 1161 in the vertical orientation. The further vacuum swing module 1161 rotates the carrier having a substrate thereon from the vertical orientation to a horizontal orientation. Thereafter, the substrate can be unloaded into a further horizontal glass handling chamber 1101. The processed substrate may be unloaded from the processing system 1000 through load lock chamber 1121, for example after the manufactured device is encapsulated in one of the thin-film encapsulation chambers 1140 or 1141.

In FIG. 10, a first transfer chamber 610, a second transfer chamber 611, a third transfer chamber 612, a fourth transfer chamber 613, a fifth transfer chamber 614, and a sixth transfer chamber 615 are provided. According to embodiments described herein, at least two transfer chambers are included in a manufacturing system, typically 2 to 8 transfer chambers can be included in the manufacturing system. Several deposition apparatuses, for example 9 deposition apparatuses 200 in FIG. 11, each having a vacuum chamber 110 and each being exemplarily connected to one of the transfer chambers are provided. According to some embodiments, one or more of the vacuum chambers of the deposition apparatuses are connected to the transfer chambers via gate valves 205.

Alignment units 112 can be provided at the vacuum chambers 110. According to yet further embodiments, which can be combined with other embodiments described herein, vacuum maintenance chambers 210 can be connected to the vacuum chambers 110, for example via gate valve 207. The vacuum maintenance chambers 210 allow for maintenance of deposition sources in the manufacturing system 1000.

According to some embodiments, and as shown in FIG. 10, the one or more transfer chambers 610-615 are provided along a line for providing an in-line transportation system portion. According to some embodiments described herein, which can be combined with other embodiments described herein, a dual track transportation arrangement is provided wherein the transfer chambers include a first track 1111 and a second track 1112 in order to transfer carriers, i.e. carriers supporting substrates, along at least one of the first track and the second track. The first tracks 1111 and the second tracks 1112 in the transfer chambers provide a dual track transportation arrangement in the manufacturing system 1000.

According to yet further embodiments, which can be combined with other embodiments described herein, one or more of the transfer chambers 610-615 are provided as a vacuum rotation module. The first track 1111 and the second track 1112 can be rotated by at least 90°, for example by 90°, 180° or 360°. The carriers on the tracks are rotated in the position to be transferred in one of the vacuum chambers of the deposition apparatuses 200 or one of the other vacuum chambers described below. The transfer chambers are configured to rotate the vertically oriented carriers and/or substrates, wherein for example that tracks in the transfer chambers are rotated around a vertical rotation axis. This is indicated by the arrows in FIG. 10.

According to some embodiments, which can be combined with other embodiments described herein, the transfer chambers are vacuum rotation modules for a rotation substrate under a pressure below 10 mbar. According to yet further embodiments, which can be combined with other embodiments described herein, a further track is provided within the two or more transfer chambers (610-615), wherein a carrier return track is provided. According to typical embodiments, the carrier return track 1125 can be provided between the first track 1111 and second track 1112. The carrier return track 1125 allows for returning empty carriers from the further vacuum swing module 1161 to the vacuum swing module 1160 under vacuum conditions. Returning the carriers under vacuum conditions and optionally under controlled inert atmosphere (e.g. Ar, N₂ or combinations thereof) reduces the carriers' exposure to ambient air. Contact to moisture can be reduced or avoided. Thus, the outgassing of the carriers during manufacturing of the devices in the manufacturing system 1000 can be reduced. This may improve the quality of the manufactured devices and/or the carriers can be in operation without being cleaned for an extended time.

FIG. 10 further shows a first pretreatment chamber 1130 and a second pretreatment chamber 1131. A robot (not shown) or another handling system can be provided in the substrate handling chamber 1100. The robot or the another handling system can load the substrate from the load lock chamber 1120 in the substrate handling chamber 1100 and transfer the substrate into one or more of the pretreatment chambers (1130, 1131). For example, the pretreatment chambers can include a pretreatment tool selected from the group consisting of: plasma pretreatment of the substrate, cleaning of the substrate, UV and/or ozone treatment of the substrate, ion source treatment of the substrate, RF or microwave plasma treatment of the substrate, and combinations thereof. After pretreatment of the substrates, the robot or another handling system transfers the substrate out of the pretreatment chamber via the substrate handling chamber into the vacuum swing module 1160. In order to allow for venting the load lock chamber 1120 for loading of the substrates and/or for handling of the substrate in the substrate handling chamber 1100 under atmospheric conditions, a gate valve 205 is provided between the substrate handling chamber 1100 and the vacuum swing module 1160. Accordingly, the substrate handling chamber 1100, and if desired one or more of the load lock chamber 1120, the first pretreatment chamber 1130 and the second pretreatment chamber 1131, can be evacuated before the gate valve 205 is opened and the substrate is transferred into the vacuum swing module 1160. Accordingly, loading, treatment and processing of substrates may be conducted under atmospheric conditions before the substrate is loaded into the vacuum swing module 1160.

According to embodiments described herein, which can be combined with other embodiments described herein, loading, treatment and processing of substrates, which may be conducted before the substrate is loaded into the vacuum swing module 1160 is conducted while the substrate is horizontally oriented or essentially horizontally oriented. The manufacturing system 1000 as shown in FIG. 10, and according to yet further embodiments described herein, combines a substrate handling in a horizontal orientation, a rotation of the substrate in a vertical orientation, material deposition onto the substrate in the vertical orientation, a rotation of the substrate in a horizontal orientation after the material deposition, and an unloading of the substrate in a horizontal orientation.

The manufacturing system 1000 shown in FIG. 10, as well as other manufacturing systems described herein, includes at least one thin-film encapsulation chamber. FIG. 11 shows a first thin-film encapsulation chamber 1140 and a second thin-film encapsulation chamber 1141. The one or more thin-film encapsulation chambers include an encapsulation apparatus, wherein the deposited and/or processed layers, particularly an OLED material, are encapsulated between, i.e. sandwiched between, the processed substrate and a further substrate in order to protect the deposited and/or processed material from being exposed to ambient air and/or atmospheric conditions. Typically, the thin-film encapsulation can be provided by sandwiching the material between two substrates, for example glass substrates. However, other encapsulation methods like lamination with glass, polymer or metal sheets, or laser fusing of a cover glass may alternatively be applied by an encapsulation apparatus provided in one of the thin-film encapsulation chambers. In particular, OLED material layers may suffer from exposure to ambient air and/or oxygen and moisture. Accordingly, the manufacturing system 1000, for example as shown in FIG. 10, can encapsulate the thin films before unloading the processed substrate via load lock chamber 1121.

The manufacturing system 1000 shown in FIG. 10, as well as other manufacturing systems described herein, can further include a layer inspection chamber 1150. A layer inspection tool, such as an electron and/or ion layer inspection tool, can be provided in the layer inspection chamber 1150. Layer inspection can be conducted after one or more depositions steps or processing steps provided in the manufacturing system 1000. Therefore, a carrier having a substrate therein can be moved from a deposition or processing chamber to the transfer chamber 611 to which the layer inspection chamber 1150 is connected via gate valve 205. The substrate to be inspected can be transferred in the layer inspection chamber and inspected within the manufacturing system, i.e. without removing the substrate from the manufacturing system. An online layer inspection can be provided after one or more of the deposition steps or processing steps, which may be conducted in the manufacturing system 1000.

According to yet further embodiments, which can be combined with other embodiments described herein, the manufacturing system can include a carrier buffer 1421. For example, the carrier buffer can be connected to the first transfer chamber 610, which is connected to the vacuum swing module 1160 and/or the last transfer chamber, i.e. the sixth transfer chamber 615. For example, the carrier buffer can be connected to one of the transfer chambers, which is connected to one of the vacuum swing modules. Since the substrates are loaded and unloaded in the vacuum swing modules, it is beneficial if the carrier buffer 1421 is provided close to a vacuum swing module. The carrier buffer is configured to provide the storage for one or more, for example 5 to 30, carriers. The carriers in the buffer can be used during operation of the manufacturing system in the event another carrier needs to be replaced, for example for maintenance, such as cleaning.

According to yet further embodiments, which can be combined with other embodiments described herein, the manufacturing system can further include a mask shelf 1132, i.e. a mask buffer. The mask shelf 1132 is configured to provide storage for replacement masks and or masks, which need to be stored for specific deposition steps. According to methods of operating a manufacturing system 1000, a mask can be transferred from the mask shelf 1132 to a deposition apparatus 200 via the dual track transportation arrangement having the first track 1111 and the second track 1112. Thus, a mask in a deposition apparatus can be exchanged either for maintenance, such as cleaning, or for a variation of a deposition pattern without venting a deposition apparatus, without venting a transfer chamber, and/or without exposing the mask to atmospheric pressure.

FIG. 10 further shows a mask cleaning chamber 1133. The mask cleaning chamber 1133 is connected to the mask shelf 1132 via gate valve 1205. Accordingly, a vacuum tight sealing can be provided between the mask shelf 1132 and the mask cleaning chamber 1133 for cleaning of a mask. According to different embodiments, the mask can be cleaned within the manufacturing system 1000 by a cleaning tool, such as a plasma cleaning tool. A plasma cleaning tool can be provided in the mask cleaning chamber 1133. Additionally or alternatively, a further gate valve 1206 can be provided at the mask cleaning chamber 1133, as shown in FIG. 10. Accordingly, a mask can be unloaded from the manufacturing system 1000 while only the mask cleaning chamber 1133 needs to be vented. By unloading the mask from the manufacturing system, an external mask cleaning can be provided while the manufacturing system continues to be fully operating. FIG. 10 illustrates the mask cleaning chamber 1133 adjacent to the mask shelf 1132. A corresponding or similar cleaning chamber (not shown) may also be provided adjacent to the carrier buffer 1421. By providing a cleaning chamber adjacent to the carrier buffer 1421, the carrier may be cleaned within the manufacturing system 1000 or can be unloaded from the manufacturing system through the gate valve connected to the cleaning chamber.

A device such as an OLED display can be manufactured in the manufacturing system 1000 as shown in FIG. 10 as follows. This is an exemplary manufacturing method only and many other devices may be manufactured by other manufacturing methods. The substrate can be loaded into the substrate handling chamber 1100 via load lock chamber 1120. A substrate pretreatment can be provided within the pretreatment chamber 1130 and/or 1131 before the substrate is loaded in the vacuum swing module 1160. The substrate is loaded on a carrier in the vacuum swing module 1160 and rotated from a horizontal orientation to a vertical orientation. Thereafter, the substrate is transferred through the transfer chambers 610 to 615. The vacuum rotation module provided in the transfer chamber 615 is rotated such that the carrier with the substrate can be moved to the deposition apparatus provided at the lower side of transfer chamber 615 in FIG. 11. Further rotation steps of one of the vacuum rotation modules in one of the transfer chambers and transfer steps through one or more of the transfer chambers are in the following omitted for ease of reference in the description of display manufacturing according to this paragraph. In the deposition apparatus an electrode deposition is conducted in order to deposit the anode of the device on the substrate. The carrier is removed from the electrode deposition chamber and moved to one of the deposition apparatuses 200, which are connected to the transfer chamber 610, both of which are configured to deposit a first hole injection layer. The two deposition apparatuses connected to the transfer chamber 610 can, for example, be alternatively utilized for the deposition of a hole injection layer on different substrates. The carrier is then transferred to the lower chamber connected to the transfer chamber 612 (in FIG. 10), such that the first hole transportation layer can be deposited by the deposition apparatus 200 provided below the transfer chamber 612 in FIG. 10. Thereafter, the carrier is transported to the deposition apparatus 200 provided at the lower side of transfer chamber 613 in FIG. 10, such that a blue emission layer can be deposited on the first hole transportation layer. The carrier is then transported to the deposition apparatus connected at the lower end of transfer chambers 614 in order to deposit the first electron transportation layer. In a subsequent step, further hole injection layers can be deposited, for example in the deposition apparatus provided at the lower side of transfer chamber 611 in FIG. 10, before the red emission layer can be provided in the deposition apparatus at the upper side of transfer chambers 612, and the green emission layer can be deposited in the deposition apparatus provided at the upper side of transfer chamber 614 in FIG. 10. Further, electron transportation layers may be provided between the emission layers and or above the emission layers. At the end of the manufacturing, a cathode can be deposited in the deposition apparatus provided below the transfer chamber 615 in FIG. 10. According to yet further embodiments, additionally one or more exciton blocking layers (or hole blocking layers) or one or more electron injection layers may be deposited between the anode and the cathode. After deposition of the cathode, the carrier is transferred to the further vacuum swing module 1161, wherein the carrier with the substrate is rotated from the vertical orientation to a horizontal orientation. Thereafter, the substrate is unloaded from the carrier in the further substrate handling chamber 1101 and transferred to one of the thin-film encapsulation chambers 1140/1141 for encapsulating the deposited layer stack. Thereafter, the manufacturer device can be unloaded through load lock chamber 1121.

In light of the above, the embodiments described herein can provide a plurality of improvements, particularly at least one or more of the below mentioned improvements. A “random” access to all chambers can be provided for such systems using a vertical cluster approach, i.e. systems having a cluster deposition system portion. The system concepts can be implemented for both RGB and White on CF deposition by offering flexibility in adding the number of modules, i.e. deposition apparatuses. This flexibility could also be used to create redundancy. A high system uptime can be provided by a reduced or no need to vent the substrate handling or deposition chambers during routine maintenance or during mask exchange. Mask cleaning can be provided, either in-situ by optional plasma cleaning or external by offering a mask exchange interface. A high deposition source efficiency (>85%) and a high material utilization (>50%) can be provided using a scanning source approach with a 180° turning mechanism to coat 2 or more substrates alternatingly or simultaneously (source-train configuration) in one vacuum chamber. The carrier stays in vacuum or under a controlled gas environment due to an integrated carrier return track. Maintenance and pre-conditioning of the deposition sources can be provided in separate maintenance vacuum chambers or source storage chambers. A horizontal glass handling, e.g. horizontal atmospheric glass handling, can be more easily adapted using already existing glass handling equipment of an owner of a manufacturing system by implementing a vacuum swing module. An interface to a vacuum encapsulation system can be provided. There is a high flexibility to add modules for substrate inspection (on-line layer analysis), mask or carrier storage. The systems have a small footprint. Further, good scalability for current and future glass sizes can be provided.

While the foregoing is directed to embodiments of the invention, other and further embodiments of the invention may be devised without departing from the basic scope thereof, and the scope thereof is determined by the claims that follow.

1. An evaporation source for organic material, comprising:
an evaporation crucible, wherein the evaporation crucible is configured to evaporate the organic material; and
a distribution pipe with one or more outlets provided along the length of the distribution pipe, wherein the distribution pipe is in fluid communication with the evaporation crucible, and wherein the distribution pipe has a non-circular cross-section perpendicular to the length of the distribution pipe and comprises an outlet side at which the one or more outlets are provided, wherein the width of the outlet side of the cross-section is 30% or less of the maximum dimension of the cross-section.

2. The evaporation source according to claim 1, wherein the cross-section perpendicular to the length of the distribution pipe has a main section corresponding to a portion of a triangle.

3. The evaporation source according to claim 1, further comprising:
a first heating device configured for heating of the evaporation crucible; and
a second heating device, which is configured to be independently heated from the first heating device, and being configured for heating the distribution pipe.

4. The evaporation source according to claim 3, wherein
the first heating device is an electrical heater outside of the evaporation crucible.

5. The evaporation source according to claim 1, further comprising:
two or more heat shields, which surround the distribution pipe, and which are spaced apart from each other.

6. The evaporation source according to claim 5, wherein the two or more heat shields are spaced apart from each other by protrusions or spots provided at or on at least one of the two or more heat shields.

7. The evaporation source according to claim 1, wherein the one or more outlets are nozzles extending along an evaporation direction.

8. The evaporation source according to claim 7, wherein the evaporation direction is essentially horizontal.

9. The evaporation source according to claim 5, wherein the one or more outlets are nozzles extending along an evaporation direction through the two or more heat shields.

10. The evaporation source according to claim 7, wherein the width of the outlet side is perpendicular to the evaporation direction.

11. The evaporation source according to claim 1, further comprising:
an evaporator control housing configured to maintain atmospheric pressure therein, wherein the housing is configured to house at least one element selected from the group consisting of: a switch, a valve, a controller, a cooling unit, a cooling control unit, a heating control unit, a power supply, and a measurement device.

12. (canceled)

13. The evaporation source according to claim 1, wherein the distribution pipe is a vapor distribution showerhead including the one or more outlets.

14. An evaporation source array for organic materials, comprising:
a first evaporation source according to claim 1; and
at least a second evaporation source according to claim 1, wherein the one or more outlets of the first evaporation source and the one or more outlets of the second evaporation source have a distance of 25 mm or less.

15. The evaporation source array according to claim 14, wherein the distribution pipes are rotatable around an axis during evaporation; and further comprising:
one or more supports for the distribution pipes, wherein the one or more supports are connectable to a first drive or includes the first drive, wherein the first drive is configured for a translational movement of the one or more supports and the distribution pipes.

16. The evaporation source according to claim 1, wherein the evaporation source is configured for a translational movement and a rotation around an axis.

17. The evaporation source according to claim 2, wherein the cross-section perpendicular to the length of the distribution pipe is triangular with at least one of rounded corners and cut-off corners.

18. The evaporation source according to claim 4, wherein the first heating device is in contact with a crucible wall of the evaporation crucible.

19. The evaporation source according to claim 18, wherein the second heating device is an electrical heater outside of the distribution pipe.

20. The evaporation source according to claim 19, wherein the second heating device is in contact with a pipe wall of the distribution pipe.

21. The evaporation source according to claim 13, wherein the vapor distribution showerhead is a linear vapor distribution showerhead providing a linear source for the organic material.
